(19) United States
(12) Patent Application Publication
(10) Pub. No.: US 2015/0361548 A1
(43) Pub. Date: Dec. 17, 2015

(54) Injection Assembly in Linear Deposition Apparatus with Bulging Ridges Extending along Bottom Openings

(71) Applicant: Veeco ALD Inc., Fremont, CA (US)

(72) Inventors: Samuel S. Pak, San Ramon, CA (US); Sang In Lee, Sunnyvale, CA (US); Daniel Ho Lee, Burlingame, CA (US); Hyoseok Daniel Yang, Cupertino, CA (US)

(21) Appl. No.: 14/303,378

(22) Filed: Jun. 12, 2014

(51) Int. Cl. C23C 16/455; C23C 16/458

(52) U.S. Cl. CPC C23C 16/455; C23C 16/458

(57) ABSTRACT

Embodiments relate to an injection module assembly (IMA) including a body and injectors installed in a module block. The body is formed with a plurality of openings defined by walls extending from the bottom surface to the top surface. Each of the walls includes bulging ridges at the bottom along bottom portions of the injectors. The bulging ridges prevent gas or radicals injected by adjacent injectors from mixing at locations other than on the top surface of a substrate placed below the IMA. Accordingly, the injectors can be placed with closer proximity to each other despite the compact size of the IMA.

### BACKGROUND

1. Field of Art

The present disclosure relates to a linear deposition apparatus with narrowing bottom openings to accommodate more replaceable injectors.

2. Description of the Related Art

An atomic layer deposition (ALD) is a thin film deposition technique for depositing one or more layers of material on a substrate. ALD uses two types of chemical, one is a source precursor and the other is a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor.

ALD can be a slow process that can take an extended amount of time or many repetitions before a layer of desired thickness can be obtained. Hence, to expedite the process, a vapor deposition reactor with a unit module (so-called a linear injector), as described in U.S. Patent Application Publication No. 2009/0165715 or other similar devices may be used to expedite ALD process. The unit module includes an injection unit and an exhaust unit for a source material (a source module), and an injection unit and an exhaust unit for a reactant (a reactant module).

### SUMMARY

Embodiments relate to an injection module assembly including a plurality of injectors and a module block for mounting the injectors. The injectors are aligned along the length of the injection module assembly. Each of the injectors injects gas or radicals from its bottom portion. The module block includes walls extending between a bottom surface of the module block and a top surface of the module block. A pair of the walls forms an opening for receiving an injector between the walls. Each wall of the pair of walls includes a bulging ridge extending along a width of the body into the opening. The bottom portion of the injector is placed between bulging ridges of the pair of walls.

### BRIEF DESCRIPTION OF DRAWINGS

FIG. 1 is a cross sectional diagram of a linear deposition device, according to one embodiment.

FIG. 2 is a perspective view of a linear deposition device, according to one embodiment.

FIG. 3 is a perspective view of an injector module assembly mounted with precursor injectors and radical injectors, according to one embodiment.

FIG. 4 is a bottom view of the injector module assembly of FIG. 3A, according to one embodiment.

FIG. 5A is a perspective view of a radical injector, according to one embodiment.

FIG. 5B is a side view of the radical injector of FIG. 5A, according to one embodiment.

FIG. 6A is a perspective view of a precursor injector, according to one embodiment.

FIG. 6B is a side view of the precursor injector of FIG. 6A, according to one embodiment.

FIG. 7A is an exploded view of the injector module assembly, according to one embodiment.

FIG. 7B is a front view of a body of the injector module assembly before mounting the precursor injectors and the radical injectors, according to one embodiment.

FIG. 8 is a cross sectional view of the injector module assembly mounted with precursor injectors and radical injectors, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

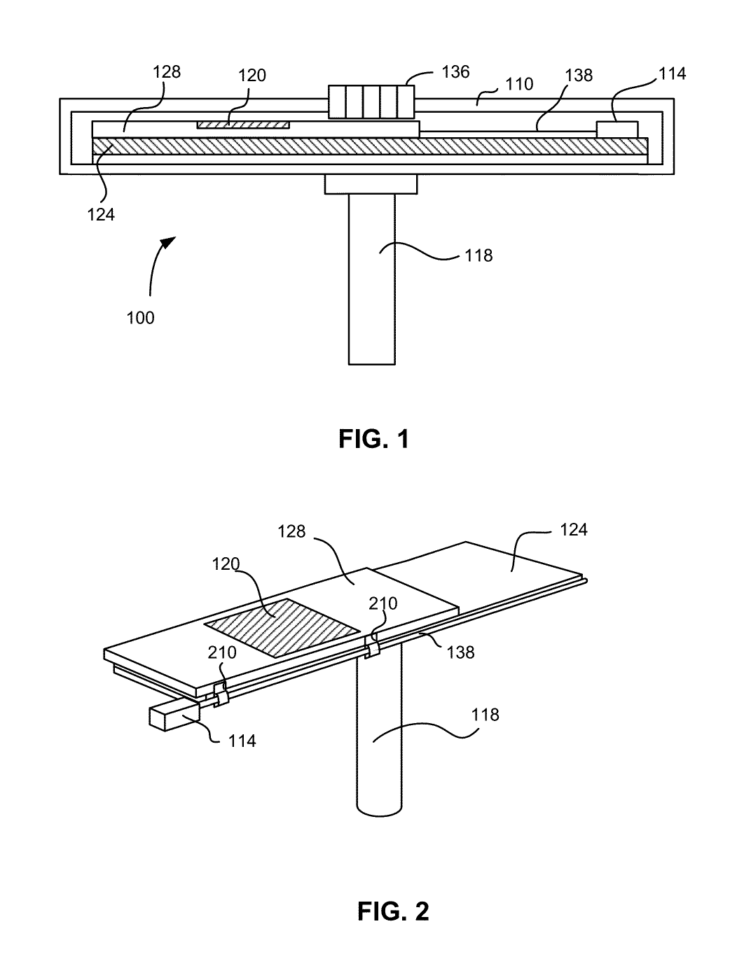

FIG. 1 is a cross sectional diagram of a linear deposition device 100, according to one embodiment. FIG. 2 is a perspective view of the linear deposition device 100 (without chamber walls to facilitate explanation), according to one embodiment. The linear deposition device 100 may include, among other components, a support pillar 118, the process chamber 110 and an injector module assembly (IMA) 136. The IMA 136 may include one or more of precursor injectors or radical injectors. Each of the injectors injects source precursors, reactant precursors, purge gases or a combination of these materials onto the substrate 120. The source precursors and/or reactant precursors may be radicals of a gas mixture.

The process chamber enclosed by the walls may be maintained in a vacuum state to prevent contaminants from affecting the deposition process. The process chamber 110 contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

In one embodiment, the susceptor 128 is secured to brackets 210 that move across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and the direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion at the bottom, top or side of the susceptor 128). Moreover, instead of moving the susceptor 128, the susceptor 128 may remain stationary and the IMA 136 may be moved.

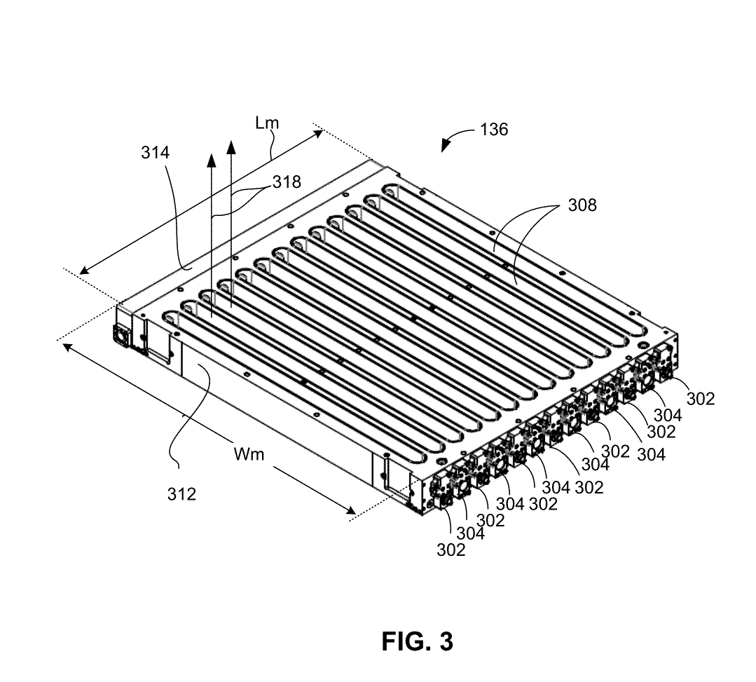

FIG. 3 is a perspective view of the IMA 136 mounted with precursor injectors 304 and radical injectors 302, according to one embodiment. The IMA 136 includes a body 312 and an end plate 314 attached to one end of the body 312. The end plate 314 and the body 312 may be secured, for example, by screws.

The body 312 is formed with openings 308 for receiving precursor injectors 304 and radical injectors 302. The precursor injectors 304 and radical injectors 302 may be mounted into the opening 308 of the body 312 using screws, for example, and the precursor injectors 304 and radical injectors 302 can be removed from the body 312 for cleaning or replacement. By enabling disassembly of the precursor injectors 304 and radical injectors 302 from the body 312, only some of the precursor injectors 304 or the radical injectors 302 can be removed from the IMA 136 for cleaning or replacement while retaining the remaining precursor injectors 304 or the radical injectors 302 and the body 312.

The IMA 136 has a width of Wm and a length of Lm. Each of the openings 308 extend along the width Wm of the IMA 136. Each of the openings 308 extend from the bottom surface to the body 312 to the top surface of the body 312. When mounted, the precursor injector 304 or the radical injector 302 injects radicals or gas through an injection port at its bottom while discharging excess precursor or gas through the top as shown by arrows 318.

As shown, the precursor injectors 304 and radical injectors 302 are mounted onto the body 312. In the example of FIG. 3, the precursor injectors 304 and radical injectors 302 are arranged in an alternating manner. However, the precursor injectors 304 and radical injectors 302 may be arranged in a different manner. Moreover, only the precursor injectors 304 or radical injectors 302 may be mounted onto the body 312. By passing the substrate 120 across the IMA 136, the substrate 120 is sequentially exposed to different radicals and precursor to deposit material using an atomic layer deposition (ALD) process.

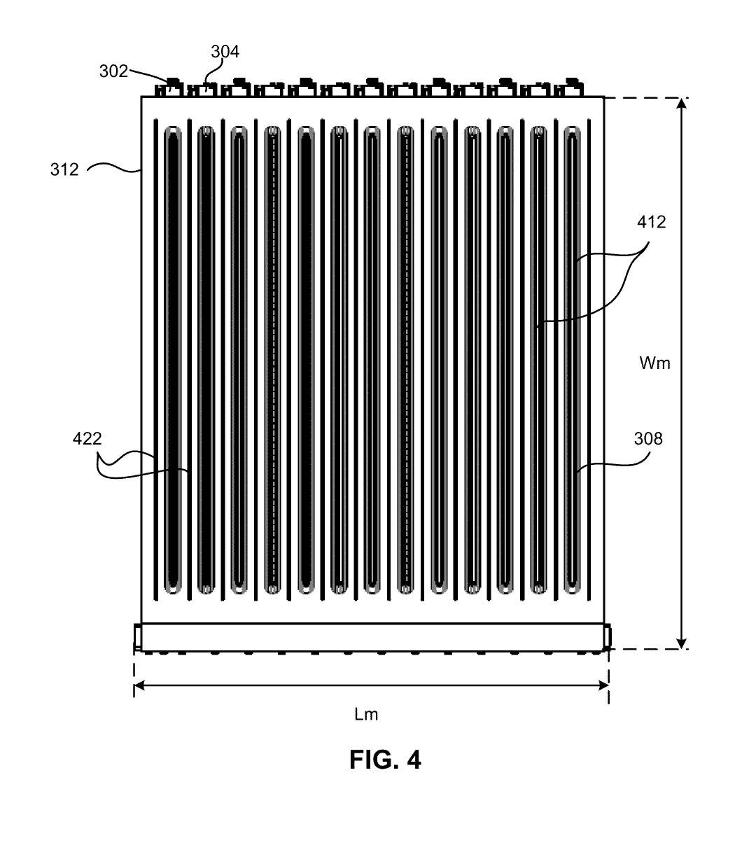

FIG. 4 is a bottom view of the injector module assembly of FIG. 3, according to one embodiment. Injection ports 412 of the precursor injectors 304 or radical injectors 302 are exposed through the openings 308 to inject gas or radicals onto the substrate 120. The body 312 is also formed with slits 422 to inject, for example, purge gas (e.g., Argon) onto the substrate 120. The slits 422 are formed at the leading end of the block 312, the trailing end of the block 312 and between the openings 308.

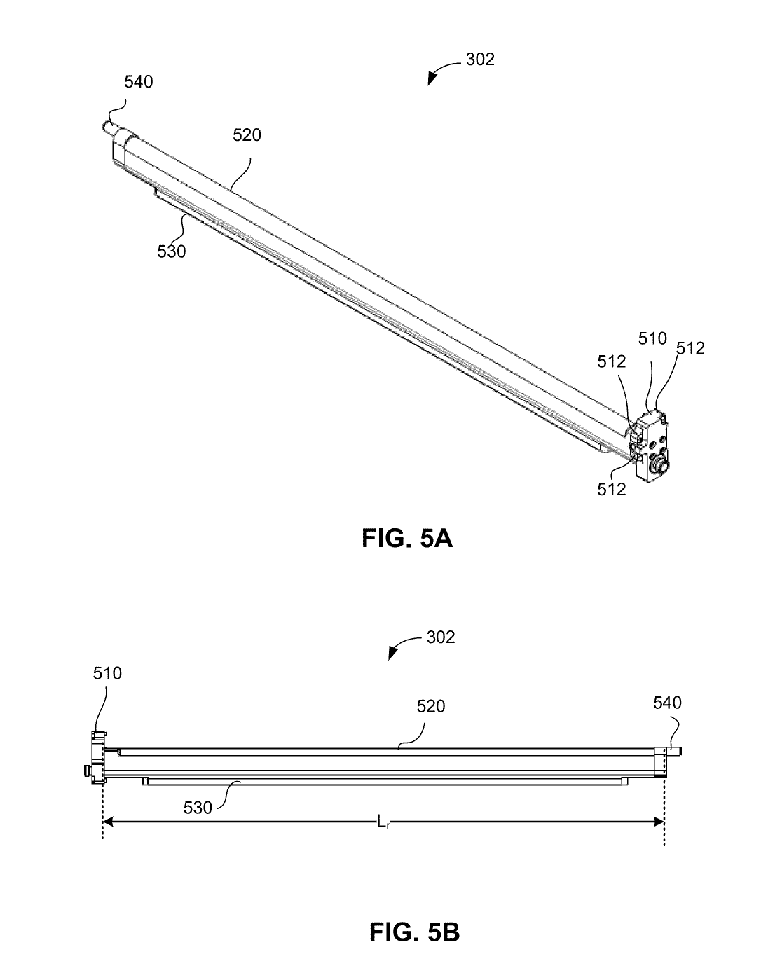

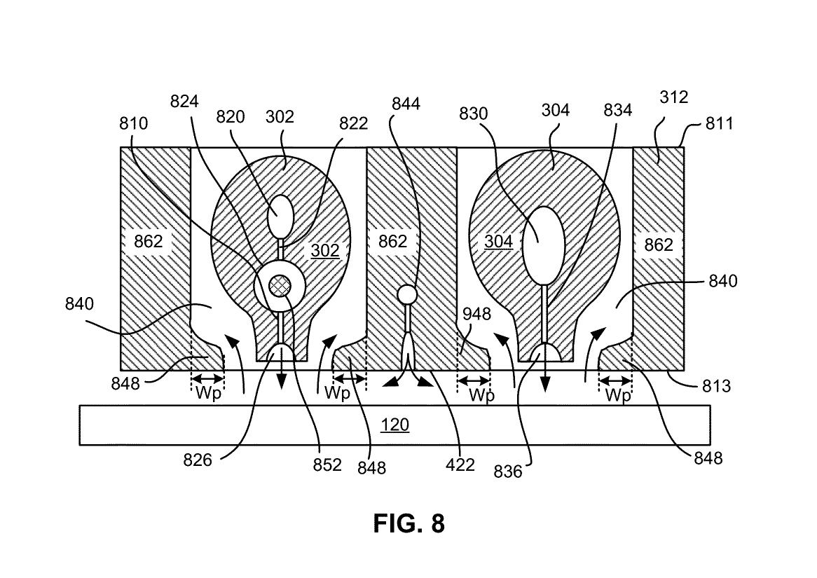

FIG. 5A is a perspective view of the radical injector 302, according to one embodiment. The radical injector 302 generates radicals using gas or mixture by generating plasma in a chamber formed in the radical injector 302. The radical injector 302 may include, among other parts, an elongated body 520, a protruding leg 540 at one end of the elongated body 520, and an end block 510 at the other end of the elongated body 520. The elongated body 520 includes injection port 530 and is formed with conduits 820, reaction chamber 826, and radical chamber 824, as described below in detail with reference to FIG. 8.

The protruding leg 540 extends along the length of the radical injector 302. When assembling, the protruding leg 540 is inserted into a support hole formed in the end plate 314. The protruding leg 540 is cylindrical in shape.

The end block 510 is used for securing the radical injector 302 to the body 312. For this purpose, the end block 510 includes screw holes 512 for receiving screws. A power line is also connected to the end block 510 to provide electric signal for generating plasma within the elongated body 520. Also, the gas or mixture for generating the radicals is injected into the radical injector 302 via the end block 510.

FIG. 5B is a side view of the radical injector 302 of FIG. 5A, according to one embodiment. The length Lr of the elongated body 520 is shorter than the width Wm of the body 312.

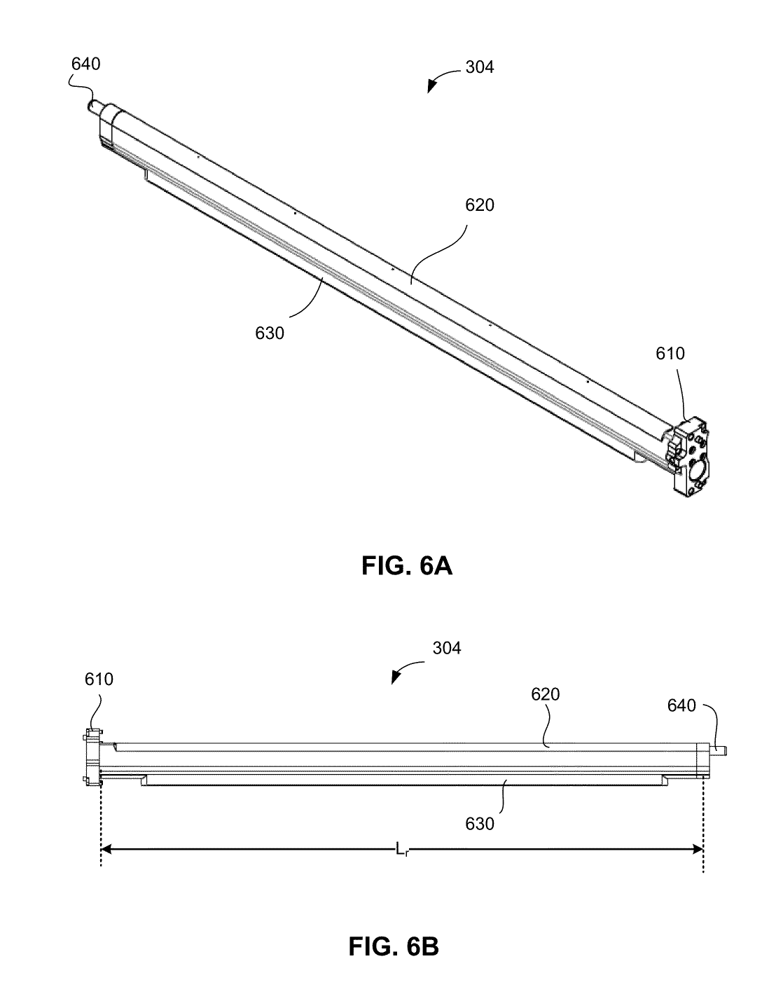

FIG. 6A is a perspective view of a precursor injector 304, according to one embodiment. The precursor injector 304 is different from the radical injector 302 in that the precursor injector 304 does not generate radicals but merely injects gas or mixture through the injection port 530 onto the substrate 120. Similar to the radical injector 302, the precursor injector 304 includes a protruding leg 640, an elongated body 620 and an end block 610. The elongated body 620 includes an injection port 630. The elongated body 620 is formed with conduit 1030 and reaction chamber 1036, as described below in detail with reference to FIG. 10.

The structure and the function of the protruding leg 640 and the end block 610 are substantially the same as the protruding leg 540 and the end block 510 except that the end block 610 is not connected to a power line, and therefore, the detailed description of the protruding leg 640 and the end block 610 is omitted herein for the sake of brevity.

FIG. 6B is a side view of the radical injector of FIG. 6A, according to one embodiment. The elongated body 620 also has a length of Lr.

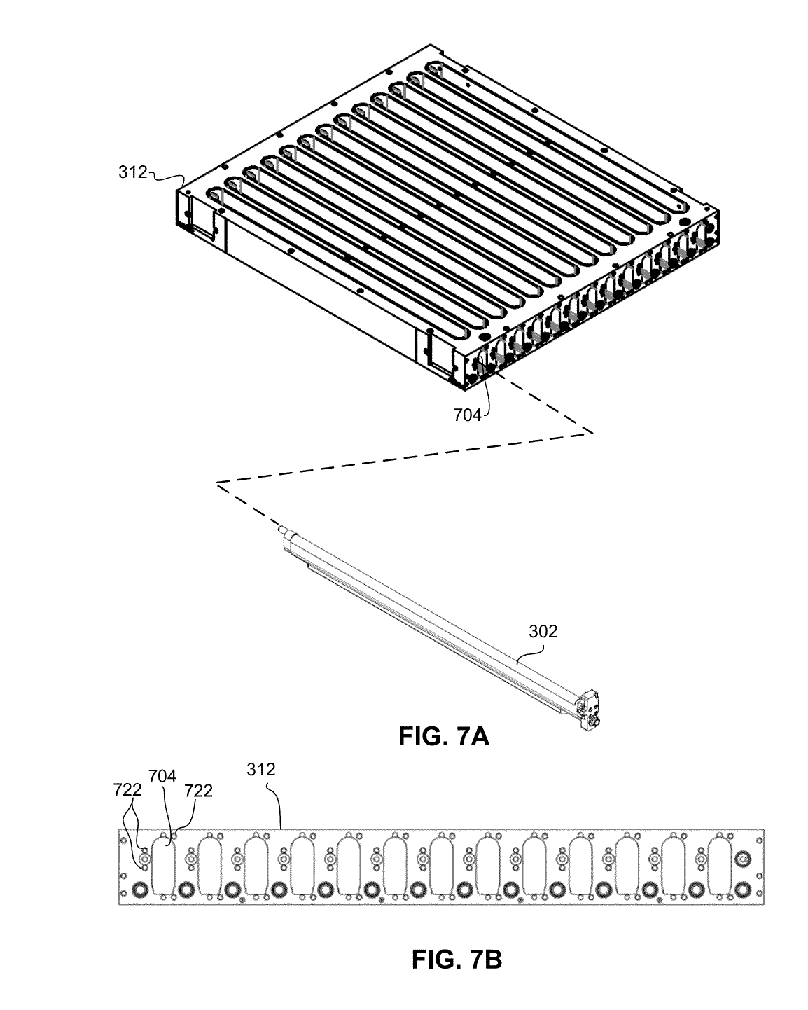

FIG. 7A is an exploded view of the IMA, according to one embodiment. The radical injector 302 is inserted into opening 308 through entrance 704. The radical injector 302 is pushed into the body 312 until the protruding leg 540 is inserted into a support hole 912. Then the screws are inserted into the holes 512 of the body 510 to secure the radical injector 302 to the body 312. The precursor injector 304 is also assembled into the body 312 in the same manner.

The removal of radical injector 302 or the precursor injector 304 can be accomplished simply by unscrewing the screws and pulling out the radical injector 302 or the precursor injector 304 from the body 312.

FIG. 7B is a front view of the injector module assembly before mounting the precursor injectors and radical injectors, according to one embodiment. Around the entrance 704, screw holes 722 are formed so that the end blocks 510, 610 can be secured by screws.

It is advantageous to make the IMA compact so that the linear deposition device 100 does not take up excessive amount of space within a fabrication facility where the linear deposition device 100 is deployed. However, when more injectors are crammed into the IMA, the IMA tends to reduce the distance between the injectors. Such reduced distance between the injectors may result in undesirable mixing of the gases or radicals injected by the injectors in areas other than on the surface of the substrate. Embodiments provide IMA that reduce the undesirable mixing of the gases despite proximate placement of the injectors.

FIG. 8 is a cross sectional view of the IMA 136 mounted with the precursor injector 304 and the radical injector 302, according to one embodiment. The body 312 includes walls 862 that extend from the bottom surface 813 to the top surface 811. The openings 308 are formed between the walls 862 to accommodate the radical injectors 302 and the precursor injectors 304.

At the bottom of the walls 862, bulging ridges 848 are formed to extend along the width of the body 312 along the same length as the injection ports 412 of the precursor injectors 304 or radical injectors 302. The width Wp of the bulging ridge 848 is dimensioned so that gaps of sufficient size are formed between the injection port 412 and the bulging ridge Wp. In this way, excess gas or radicals can be discharged via gaps 840 and the top portions of the openings 308.

The presence of bulging ridges 848 is advantageous, among other reasons, because gas or radicals injected by the injectors 302, 304 are less likely to be mixed between space between the substrate 120 and the bottom surface 813 of the body 312. The bulging ridges 848 force substantially all of the gas or radicals to be injected in regions immediately below the injectors 302, 304. In ALD processes, the deposited layer has better quality when the reaction or replacement of molecules is limited to the exposed surface of the substrate 120. Since the bulging ridges 848 prevent the mixing of gas or radicals from adjacent injectors, the injectors can be placed closer to each other.

Although FIG. 8 illustrates the width Wp of the bulging ridges 848 to be the same across different walls 862, the width of the bulging ridges may have different width at different walls for various reasons such as to control flow of the gas or the radicals in a certain manner.

The radical injector 302 is formed with a conduit 820 that extends along the length of the elongated body 520. Gas is injected into a radical chamber 824 from the conduit 820 via a channel 822. Within the radical chamber 824, radicals are formed by generating plasma between an electrode 852 and the interior surface of the radical chamber 824. The generated radicals are transferred to a reaction chamber 826 where the radicals are injected onto the substrate 120.

The precursor injector 304 is formed with a conduit 830 that extends along the length of the elongated body 620. The precursor gas is injected into a reaction chamber 836 formed in the elongated body 620 from the conduit 830 via a channel 834.

Purge gas is injected via slit 422. The purge gas is provided to the slit 422 via a conduit 844 and a channel 844 between the slit 422 and the conduit 844.

The excess radicals (or gas reverted to inert state) and part of the purge gas injected by the slit 422 is discharged via gap 840 formed between the radical injector 302 and the body 312. Similarly, excess precursor and part of the purge gas is discharged via gap 840 between the precursor injector 304 and the body 312. To create negative pressure, the IMA 136 may be connected to a vacuum source (not shown) to discharge the excess radicals, purge gas and the precursor.

While particular embodiments and applications have been illustrated and described, the disclosed embodiments are not limited to the precise construction and components disclosed herein. Various modifications, changes and variations, may be made in the arrangement, operation and details of the method and apparatus disclosed herein without departing from the spirit and scope defined in the appended claims.

1. An injection module assembly, comprising:
a plurality of injectors aligned along a length of the injection module assembly, each of the injectors configured to inject gas or radicals from a bottom portion of each of the injectors; and
a module block comprising a plurality of walls extending between a bottom surface of the module block and a top surface of the module block, a pair of the walls forming an opening for receiving an injector, each of the pair of walls comprising a bulging ridge extending along a width of the body into the opening, a bottom portion of the injector placed between bulging ridges of the pair of walls.

2. The injection module assembly of claim 1, wherein at least one of the plurality of walls is further formed with a channel for carrying a purge gas and a slit connected to the channel to inject the gas.

3. The injection module assembly of claim 2, wherein the channel extends along a width of the injection module assembly.

4. The injection module assembly of claim 2, wherein gaps are provided between the pair of walls and the injector within the opening to discharge at least part of the gas or radicals injected by the injector and the purge gas injected by the slit.

5. The injection module assembly of claim 1, wherein adjacent injectors of the plurality of injector inject different gas or radicals.

6. The injection module assembly of claim 1, wherein the gas or radicals are injected onto a substrate moving across the injection module assembly.
